(19) United States
(12) Patent Application Publication
(10) Pub. No.: US 2025/0280498 A1
(43) Pub. Date: Sep. 4, 2025

(54) INTERCONNECT SUBSTRATE AND METHOD OF MAKING INTERCONNECT SUBSTRATE

(71) Applicant: SHINKO ELECTRIC INDUSTRIES CO., LTD., Nagano (JP)

(72) Inventors: Yuna KAMIOKA, Nagano (JP); Kotaro KODANI, Nagano (JP)

(21) Appl. No.: 19/062,616

(22) Filed: Feb. 25, 2025

(30) Foreign Application Priority Data
Mar. 1, 2024 (JP) 2024-031435

(51) Int. Cl. H05K 1/11; H05K 3/42; H05K 3/46

(52) U.S. Cl. CPC H05K 1/116; H05K 3/42; H05K 3/4644; H05K 2201/09563; H05K 2201/09827

(57) ABSTRACT

An interconnect substrate includes a first interconnect layer having a first surface in which a recess is formed, an insulating layer that has a second surface facing the first surface and covers the first interconnect layer, a via hole overlapping the first interconnect layer in plan view and penetrating the insulating layer, and a second interconnect layer formed on the insulating layer and situated in contact with the first interconnect layer through the via hole.

### CROSS-REFERENCE TO RELATED APPLICATIONS

The present application is based on and claims priority to Japanese Patent Application No. 2024-031435 filed on Mar. 1, 2024, with the Japanese Patent Office, the entire contents of which are incorporated herein by reference.

### FIELD

The disclosures herein relate to interconnect substrates and methods of making an interconnect substrate.

### BACKGROUND

Manufacturing an interconnect substrate generally involves forming an insulating layer over an interconnect layer, creating a via hole in the insulating layer, performing a desmearing process, and forming another interconnect layer within the via hole and on the insulating layer.

In recent years, improving the connection reliability between interconnect layers has become a priority

It may be desired to provide an interconnect substrate structured to improve connection reliability between interconnect layers, and a method of making such an interconnect substrate.

### RELATED ART DOCUMENTS

### Patent Documents

[Patent Document 1] Japanese Laid-Open Patent Publication No. 2000-244127

### SUMMARY

According to an aspect of the embodiment, an interconnect substrate includes a first interconnect layer having a first surface in which a recess is formed, an insulating layer that has a second surface facing the first surface and covers the first interconnect layer, a via hole overlapping the first interconnect layer in plan view and penetrating the insulating layer, and a second interconnect layer formed on the insulating layer and situated in contact with the first interconnect layer through the via hole, wherein in a cross section including a center line that is perpendicular to the second surface and passes through a center of an upper edge of the via hole in plan view, a surface of the recess includes a first point located at an edge of the recess and a second point located on the center line, and when a portion of the surface of the recess between the first point and the second point is approximated by a curve with only one inflection point, a first angle between a first line segment connecting the first point and a third point and a line segment extending from the first point to the center line on the second surface is less than 90 degrees, a second angle between the first line segment and a second line segment connecting the third point and a fourth point is greater than 90 degrees, a third angle between the second line segment and a third line segment connecting the fourth point and the second point is greater than 90 degrees, the third point is a point where a curvature of the curve is maximum between the first point and the inflection point, and the fourth point is a point where the curvature of the curve is maximum between the second point and the inflection point

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating an example of an interconnect substrate according to an embodiment;

FIG. 2 is a view illustrating an example of positional relationships mainly between a via hole and a recess;

FIG. 3 is a cross-sectional view illustrating an example of the shape of the recess;

FIGS. 4A through 4C are cross-sectional views illustrating an example of a method of making the interconnect substrate according to the embodiment;

FIGS. 5A through 5C are cross-sectional views illustrating the example of the method of making the interconnect substrate according to the embodiment;

FIGS. 6A and 6B are cross-sectional views illustrating the example of the method of making the interconnect substrate according to the embodiment;

FIGS. 7A through 7C are cross-sectional views illustrating an example of a method of forming the via hole, the recess, and an interconnect layer;

FIGS. 8A and 8B are cross-sectional views illustrating the example of the method of forming the via hole, the recess, and the interconnect layer; and

FIGS. 9A and 9B are cross-sectional views illustrating the example of the method of forming the via hole, the recess, and the interconnect layer.

### DESCRIPTION OF EMBODIMENTS

Improving connection reliability between interconnect layers may conceivably be achieved by forming a recess on the surface of the interconnect layer upon forming a via hole, and forming another interconnect layer by plating that fills the interior of the recess. However, upon manufacturing such an interconnect substrate, the inventors of the present invention found that the plating solution was not supplied to the edge of the recess, resulting in the formation of a gap in the recess. Any gap formed in the recess may pose a risk of failing to improve the connection reliability sufficiently. Upon this finding, the inventors of the present invention have made further study to prevent the occurrence of a gap in the recess, and have come up with the following embodiments.

In the following, an embodiment of the present disclosure will be described with reference to the accompanying drawings. In the present specification and the drawings, components having substantially the same functional configuration are referred to by the same reference numerals, and a duplicate description thereof may be omitted.

### Structure of Interconnect Substrate of Embodiment

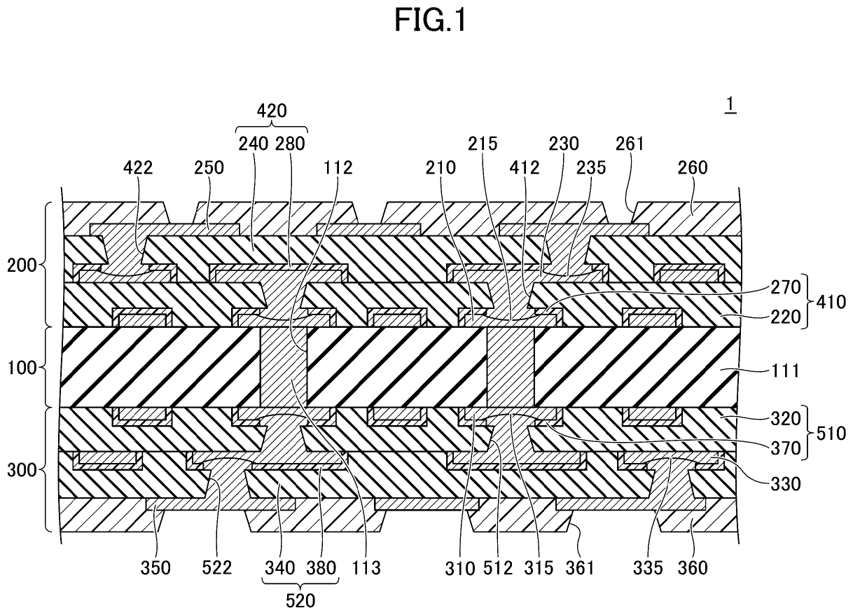

First, the structure of an interconnect substrate according to an embodiment will be described. FIG. 1 is a cross-sectional view illustrating an example of an interconnect substrate according to an embodiment.

As illustrated in FIG. 1, an interconnect substrate 1 according to the embodiment includes, for example, a core layer 100, a buildup layer 200 formed on the A-side surface of the core layer 100, and a buildup layer 300 formed on the B-side surface of the core layer 100. The interconnect substrate 1 may be a coreless substrate without a core layer.

In this embodiment, for convenience, the side of an object oriented in the same direction as the buildup layer 200 side of the core layer 100 is referred to as an upper side or an A side, and the side of the object oriented in the same direction as the buildup layer 300 side of the core layer 100 is referred to as a lower side or a B side. The surface of an object on the upper side thereof is referred to as an A-side surface or an upper surface, and the surface of the object on the lower side thereof is referred to as a B-side surface or the lower surface. However, the interconnect substrate 1 may be placed upside down when used, or may be arranged at any angle. The plan view refers to the view of an object as seen from the direction normal to the A-side surface of the core layer 100. The plane shape refers to the shape of an object as viewed from the direction normal to the A-side surface of the core layer 100.

The core layer 100 includes an insulating substrate 111 having a plurality of through holes 112 formed therethrough and an electrically conductive layer 113 formed on the inner surfaces of the through holes 112. The material of the substrate is, for example, glass epoxy or the like, and the material of the conductive layer 113 is, for example, copper (Cu) or the like. The core layer 100 may have a filling material filling the space inside the conductive layer 113.

The buildup layer 200 includes interconnect layers 210, 230 and 250, insulating layers 410 and 420, and a solder resist layer 260. The buildup layer 300 includes interconnect layers 310, 330 and 350, insulating layers 510 and 520, and a solder resist layer 360. The insulating layer 410 is disposed between the interconnect layers 210 and 230 adjacent to each other in the thickness direction. The insulating layer 420 is disposed between the interconnect layers 230 and 250 adjacent to each other in the thickness direction. The insulating layer 510 is disposed between the interconnect layers 310 and 330 adjacent to each other in the thickness direction. The insulating layer 520 is disposed between the interconnect layers 330 and 350 adjacent to each other in the thickness direction. The insulating layer 410 includes an insulating layer 220 and an adhesion enhancing film 270, and the insulating layer 420 includes an insulating layer 240 and an adhesion enhancing film 280. The insulating layer 510 includes an insulating layer 320 and an adhesion enhancing film 370, and the insulating layer 520 includes an insulating layer 340 and an adhesion enhancing film 380.

The interconnect layer 210 is formed on the A-side surface of the core layer 100. The interconnect layer 310 is formed on the B-side surface of the core layer 100. The interconnect layers 210 and 310 are electrically connected to each other by the conductive layer 113. The material of the interconnect layers 210 and 310 is, for example, copper (Cu) or the like. The thicknesses of the interconnect layers 210 and 310 are, for example, about 10 μm to 30 μm.

The adhesion enhancing film 270 is formed on the A-side surface and the side surfaces of the interconnect layer 210. The adhesion enhancing film 270 covers the A-side surface and the side surfaces of the interconnect layer 210. The adhesion enhancing film 270 is formed of a material having two types of functional groups with different reactivities within a single molecule. The material of the adhesion enhancing film 270 is, for example, a silane coupling agent or a titanium coupling agent. The thickness of the adhesion enhancing film 270 is, for example, about 3 nm to 8 nm.

In the silane coupling agent, a functional group which chemically bonds with an organic material such as a resin preferably contains an amino group, an epoxy group, a mercapto group, an isocineate group, a methacryloxy group, an acryloxy group, a ureido group, or a sulfide group. An optimum functional group is selected according to the type of resin to be chemically bonded with the silane coupling agent.

In the silane coupling agent, a functional group which chemically bonds with an inorganic material such as a metal preferably contains an azole group, a silanol group, a methoxy group, or an ethoxy group. An optimum functional group is selected according to the type of metal to be chemically bonded with the silane coupling agent.

The insulating layer 220 is formed so as to cover the interconnect layer 210 and the adhesion enhancing film 270 on the A-side surface of the core layer 100. The material of the insulating layer 220 is, for example, an insulating resin mainly composed of an epoxy-based resin or a polyimide-based resin. The thickness of the insulating layer 220 is, for example, about 30 μm to 40 μm. The insulating layer 220 may contain a filler such as silica (SiO₂). The filler content in the insulating layer 220 may be appropriately set according to the required coefficient of thermal expansion (CTE). The adhesion enhancing film 270 improves adhesion between the interconnect layer 210 and the insulating layer 220. That is, the provision of the adhesion enhancing film 270 achieves higher adhesion between the interconnect layer 210 and the insulating layer 220 than when the interconnect layer 210 and the insulating layer 220 are in direct contact.

A recess 215 is formed on the A-side surface of the interconnect layer 210. A via hole 412 is formed in the insulating layer 410. The via hole 412 penetrates the insulating layer 410. That is, the via hole 412 penetrates the insulating layer 220 and the adhesion enhancing film 270. The via hole 412 overlaps the interconnect layer 210 in plan view and reaches the interconnect layer 210. The via hole 412 overlaps the recess 215 in plan view and connects to the recess 215.

The interconnect layer 230 is formed on the A-side surface of the insulating layer 220. The interconnect layer 230 includes a via conductor positioned within the via hole 412 and the recess 215, and an interconnect pattern on the A-side surface of the insulating layer 220. The interconnect pattern of the interconnect layer 230 is electrically connected to the interconnect layer 210 via the via conductor. The material and thickness of the interconnect layer 230 are substantially the same as, for example, the interconnect layer 210.

The adhesion enhancing film 280 is formed on the A-side surface and the side surfaces of the interconnect layer 230. The adhesion enhancing film 280 covers the A-side surface and the side surfaces of the interconnect layer 230. The material and thickness of the adhesion enhancing film 280 are substantially the same as, for example, the adhesion enhancing film 270.

The insulating layer 240 is formed so as to cover the interconnect layer 230 and the adhesion enhancing film 280 on the A-side surface of the insulating layer 220. The material and thickness of the insulating layer 240 are, for example, substantially the same as those of the insulating layer 220. The insulating layer 240 may contain a filler such as silica (SiO₂). The content of the filler in the insulating layer 240 is, for example, substantially the same as that of the insulating layer 220. The adhesion enhancing film 280 improves adhesion between the interconnect layer 230 and the insulating layer 240. That is, the provision of the adhesion enhancing film 280 achieves higher adhesion between the interconnect layer 230 and the insulating layer 240 than when the interconnect layer 230 and the insulating layer 240 are in direct contact.

A recess 235 is formed on the A-side surface of the interconnect layer 230. A via hole 422 is formed in the insulating layer 420. The via hole 422 penetrates the insulating layer 420. That is, the via hole 422 penetrates the insulating layer 240 and the adhesion enhancing film 280. The via hole 422 overlaps the interconnect layer 230 in plan view and reaches the interconnect layer 230. The via hole 422 overlaps the recess 235 in plan view and connects to the recess 235.

The interconnect layer 250 is formed on the A-side surface of the insulating layer 240. The interconnect layer 250 includes a via conductor positioned within the via hole 422 and the recess 235, and an interconnect pattern on the A-side surface of the insulating layer 240. The interconnect pattern of the interconnect layer 250 is electrically connected to the interconnect layer 230 via the via conductor. The material and the thickness of the interconnect layer 250 are substantially the same as those of the interconnect layer 210, for example. An adhesion enhancing film (not illustrated) may be formed on the A-side surface and the side surfaces of the interconnect layer 250.

The solder resist layer 260 is formed on the A-side surface of the insulating layer 240 so as to cover the interconnect layer 250. An opening 261 is formed in the solder resist layer 260. The opening 261 penetrates the solder resist layer 260. The opening 261 overlaps an electrode pad which is a part of the interconnect layer 250 in plan view and reaches the electrode pad.

The adhesion enhancing film 370 is formed on the B-side surface and the side surfaces of the interconnect layer 310. The adhesion enhancing film 370 covers the B-side surface and the side surfaces of the interconnect layer 310. The material and thickness of the adhesion enhancing film 370 are, for example, substantially the same as those of the adhesion enhancing film 270.

The insulating layer 320 is formed on the B-side surface of the core layer 100 so as to cover the interconnect layer 310 and the adhesion enhancing film 370. The material and thickness of the insulating layer 320 are, for example, substantially the same as those of the insulating layer 220. The insulating layer 320 may contain a filler such as silica (SiO₂). The filler content of the insulating layer 320 is, for example, substantially the same as that of the insulating layer 220. The adhesion enhancing film 370 improves adhesion between the interconnect layer 310 and the insulating layer 320. That is, the provision of the adhesion enhancing film 370 achieves higher adhesion between the interconnect layer 310 and the insulating layer 320 than when the interconnect layer 310 and the insulating layer 320 are in direct contact.

A recess 315 is formed on the B-side surface of the interconnect layer 310. A via hole 512 is formed in the insulating layer 510. The via hole 512 penetrates the insulating layer 510. That is, the via hole 512 penetrates the insulating layer 320 and the adhesion enhancing film 370. The via hole 512 overlaps the interconnect layer 310 in plan view and reaches the interconnect layer 310. The via hole 512 overlaps the recess 315 in plan view and connects to the recess 315.

The interconnect layer 330 is formed on the B-side surface of the insulating layer 320. The interconnect layer 330 includes a via conductor positioned within the via hole 512 and the recess 315, and an interconnect pattern on the B-side surface of the insulating layer 320. The interconnect pattern of the interconnect layer 330 is electrically connected to the interconnect layer 310 via the via conductor. The material and the thickness of the interconnect layer 330 are substantially the same as those of the interconnect layer 210, for example.

The adhesion enhancing film 380 is formed on the B-side surface and the side surfaces of the interconnect layer 330. The adhesion enhancing film 380 covers the B-side surface and the side surfaces of the interconnect layer 330. The material and thickness of the adhesion enhancing film 380 are, for example, substantially the same as those of the adhesion enhancing film 270.

The insulating layer 340 is formed so as to cover the interconnect layer 330 and the adhesion enhancing film 380 on the B-side surface of the insulating layer 320. The material and thickness of the insulating layer 340 are, for example, substantially the same as those of the insulating layer 220. The insulating layer 340 may contain a filler such as silica (SiO₂). The content of the filler in the insulating layer 340 is, for example, substantially the same as that of the insulating layer 220. The adhesion enhancing film 380 improves the adhesion between the interconnect layer 330 and the insulating layer 340. That is, when the adhesion enhancing film 380 is provided, the adhesion between the interconnect layer 330 and the insulating layer 340 is higher than when the interconnect layer 330 and the insulating layer 340 are in direct contact.

A recess 335 is formed on the B-side surface of the interconnect layer 330. A via hole 522 is formed in the insulating layer 520. The via hole 522 penetrates the insulating layer 520. That is, the via hole 522 penetrates the insulating layer 340 and the adhesion enhancing film 380. The via hole 522 overlaps the interconnect layer 330 in plan view and reaches the interconnect layer 330. The via hole 522 overlaps the recess 335 in plan view and connects to the recess 335.

The interconnect layer 350 is formed on the B-side surface of the insulating layer 340. The interconnect layer 350 includes a via conductor situated within the via hole 522 and the recess 335, and an interconnect pattern on the B-side surface of the insulating layer 340. The interconnect pattern of the interconnect layer 350 is electrically connected to the interconnect layer 330 via the via conductor. The material and thickness of the interconnect layer 350 are substantially the same as, for example, the interconnect layer 210. An adhesion enhancing film (not illustrated) may be formed on the B-side surface and the side surfaces of the interconnect layer 350.

The solder resist layer 360 is formed on the B-side surface of the insulating layer 340 so as to cover the interconnect layer 350. An opening 361 is formed in the solder resist layer 360. The opening 361 penetrates the solder resist layer 360. The opening 361 overlaps an electrode pad which is a part of the interconnect layer 350 in plan view and reaches the electrode pad.

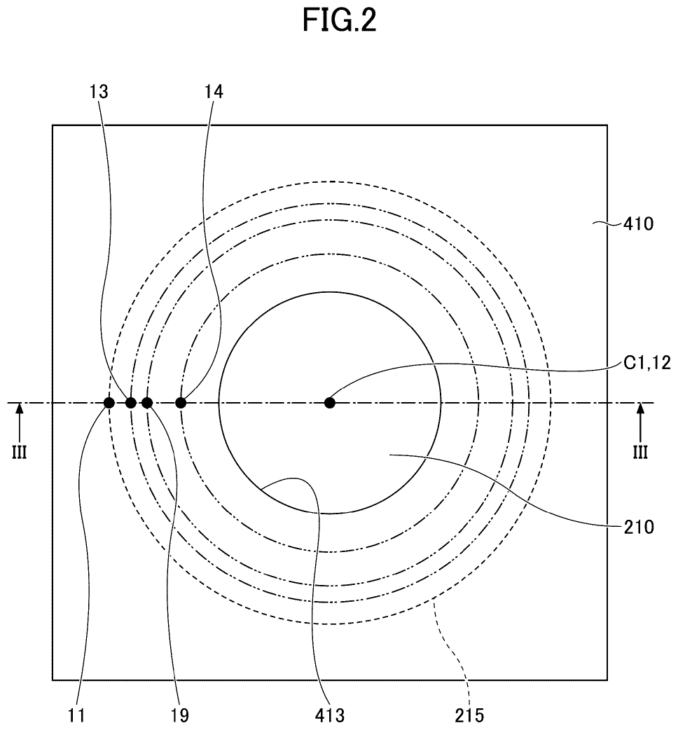

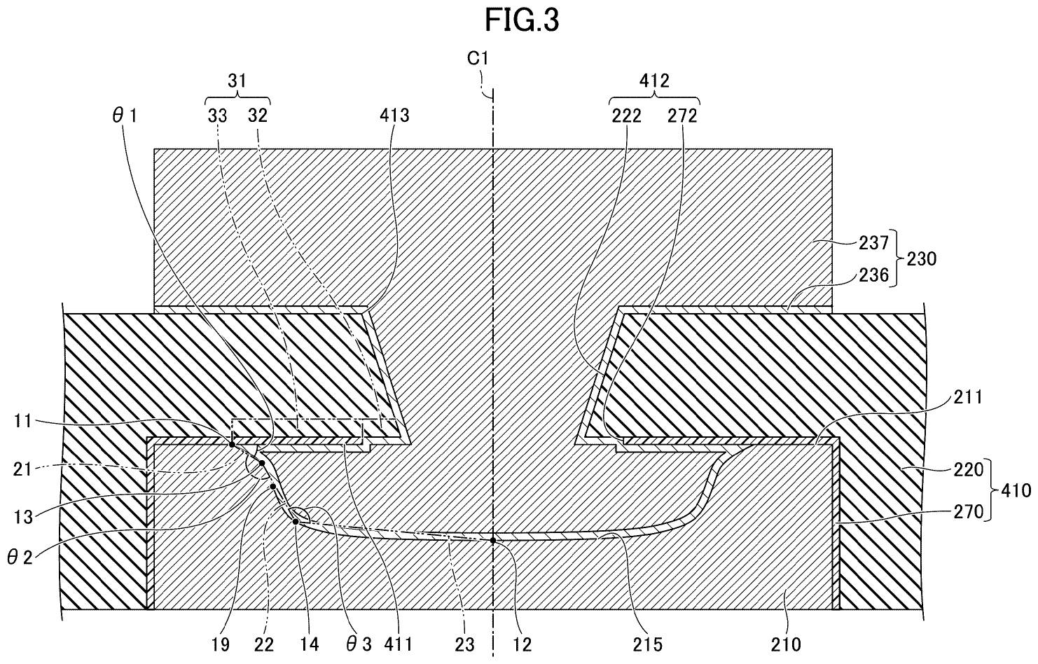

The interconnect layer 210, the adhesion enhancing film 270, the insulating layer 220, and the interconnect layer 230 will now be described in more detail. FIG. 2 is a view illustrating an example of positional relationships mainly between the via hole 412 and the recess 215. FIG. 3 is a cross-sectional view illustrating an example of the shape of the recess 215. FIG. 3 corresponds to a cross-sectional view along the line III-III in FIG. 2.

As illustrated in FIGS. 2 and 3, the recess 215 is formed on the upper surface 211, which is the A-side surface of the interconnect layer 210. The insulating layer 410 has a lower surface 411, which is the B-side surface. The lower surface 411 of the insulating layer 410 faces the upper surface 211 of the interconnect layer 210. The upper surface 211 of the interconnect layer 210 is an example of a first surface, and the lower surface 411 of the insulating layer 410 is an example of a second surface.

The via hole 412 has a hole portion 222 formed through the insulating layer 220 and a hole portion 272 formed through the adhesion enhancing film 270. The hole portion 222 may be an inverted truncated conical recess. That is, the hole portion 222 is structured such that the opening diameter at the upper end may be larger than the opening diameter at the lower end. The hole portion 272 connects to the hole portion 222 and the recess 215. The aperture of the hole portion 272 is larger than the aperture at the lower end of the hole portion 222. The aperture at the upper end of the recess 215 is larger than the aperture of the hole portion 272. In plan view, thus, the hole portion 272 is inside the upper end of the recess 215, and the lower end of the hole portion 222 is inside the hole portion 272.

As will be described later, the recess 215 may be formed by wet etching. The surface of the recess 215, which is a part of the upper surface 211, may have fine surface irregularities due to wet etching. In FIG. 3, the fine irregularities of the surface of the recess 215 are omitted. FIG. 3 illustrates a cross section including a center line C1 that is perpendicular to the lower surface 411 and passes through the center of the upper edge 413 of the via hole 412 in plan view. In this cross section, the surface of the recess 215 includes a first point 11 located on the edge of the recess 215 and a second point 12 located on the center line C1.

When the portion of the surface of the recess 215 between the first point 11 and the second point 12 is approximated by a curve with only one inflection point, the recess 215 includes a third point 13 having the maximum curvature between the first point 11 and an inflection point 19, and a fourth point 14 having the maximum curvature between the second point 12 and the inflection point 19.

The first angle between a first line segment 21 connecting the first point 11 and the third point 13 and a line segment extending from the first point to the center line CL on the lower surface 411 of the insulating layer 410 is acute, the second angle between the first line segment 21 and a second line segment 22 connecting the third point 13 and the fourth point 14 is obtuse, and the third angle between the second line segment 22 and a third line segment 23 connecting the fourth point 14 and the second point 12 is obtuse. In other words, the angle θ1 representing the first angle is less than 90 degrees, the angle θ2 representing the second angle is greater than 90 degrees, and the angle θ3 representing the third angle is greater than 90 degrees.

As described above, the surface of the recess 215 has, on both sides of the center line C1 in the cross-sectional view, a first inclined portion which gently slopes downwards from the first point 11 to the second point 12, a second inclined portion which steeply slopes downwards from the first inclined portion, and a third inclined portion which gently slopes downwards from the second inclined portion. Generally, the first inclined portion corresponds to the portion between the first point 11 and the third point 13, the second inclined portion corresponds to the portion between the third point 13 and the fourth point 14, and the third inclined portion corresponds to the portion between the fourth point 14 and the second point 12.

The interconnect layer 230 is in contact with the surface of the recess 215, the portion of the lower surface 411 of the insulating layer 410 facing the recess 215, the inner wall surface of the via hole 412, and the A-side surface of the insulating layer 410. The interconnect layer 230 has a seed layer 236 and a plating layer 237. The seed layer 236 directly covers the surface of the recess 215, the portion of the lower surface 411 of the insulating layer 410 facing the recess 215, the inner wall surface of the via hole 412, and the A-side surface of the insulating layer 410. The plating layer 237 is provided on the seed layer 236. The material of the seed layer 236 and the plating layer 237 is copper (Cu) or the like.

The insulating layer 410 has a first region 31 extending to a depth of 2 μm or less from the portion of the lower surface 411 facing the recess 215. The first region 31 includes a second region 32 including the inner wall surface of the via hole, and a third region 33 connected to the second region 32 and located between the second region 32 and the first point 11 in plan view. The second region 32 and the third region 33 include the insulating layer 220. The third region 33 includes the adhesion enhancing film 270, but the second region 32 does not include the adhesion enhancing film 270. As a result, when the insulating layer 220 includes a filler and the adhesion enhancing film 270 does not include the filler, the density of the filler in the second region 32 is higher than that in the third region 33.

The interconnect layer 230, the adhesion enhancing film 280, the insulating layer 240, and the interconnect layer 250 are also laminated to each other in substantially the same manner as the interconnect layer 210, the adhesion enhancing film 270, the insulating layer 220, and the interconnect layer 230. The interconnect layer 310, the adhesion enhancing film 370, the insulating layer 320, and the interconnect layer 330 are also laminated to each other in substantially the same manner as the interconnect layer 210, the adhesion enhancing film 270, the insulating layer 220, and the interconnect layer 230. The interconnect layer 330, the adhesion enhancing film 380, the insulating layer 340, and the interconnect layer 350 are also laminated to each other in substantially the same as manner the interconnect layer 210, the adhesion enhancing film 270, the insulating layer 220, and the interconnect layer 230.

In the relationship between the interconnect layers 210 and 230, the interconnect layer 210 is an example of a first interconnect layer, and the interconnect layer 230 is an example of a second interconnect layer. In the relationship between the interconnect layers 230 and 250, the interconnect layer 230 is an example of a first interconnect layer, and the interconnect layer 250 is an example of a second interconnect layer. In the relationship between the interconnect layers 310 and 330, the interconnect layer 310 is an example of a first interconnect layer, and the interconnect layer 330 is an example of a second interconnect layer. In the relationship between the interconnect layers 330 and 350, the interconnect layer 330 is an example of a first interconnect layer, and the interconnect layer 350 is an example of a second interconnect layer.

### Method of Making Interconnect Substrate According to Embodiment

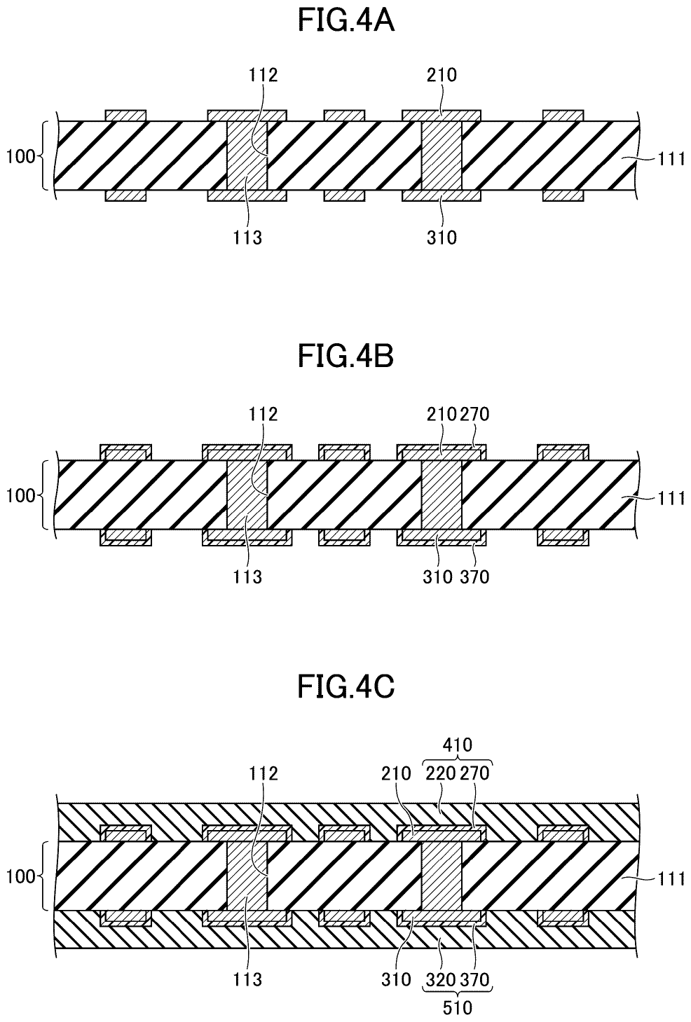

In the following, a method of making the interconnect substrate 1 according to the embodiment will be described. FIGS. 4A through 4C to FIGS. 6A and 6B are cross-sectional views illustrating an example of the method of making the interconnect substrate according to the embodiment.

First, as illustrated in FIG. 4A, a laminate of the core layer 100, the interconnect layer 210, and the interconnect layer 310 is prepared. The core layer 100 includes the insulating substrate 111 having the through holes 112 and the conductive layer 113.

Next, as illustrated in FIG. 4B, the adhesion enhancing film 270 is formed on the upper and side surfaces of the interconnect layer 210, and the adhesion enhancing film 370 is formed on the lower and side surfaces of the interconnect layer 310. The adhesion enhancing films 270 and 370 are formed using, for example, a silane coupling agent.

To form the adhesion enhancing films 270 and 370 using the silane coupling agent, for example, the structure illustrated in FIG. 4A may be immersed in a diluted solution of the silane coupling agent. Alternatively, the adhesion enhancing film 270 may be formed by spray-coating the upper and side surfaces of the interconnect layer 210 of the structure illustrated in FIG. 4A with a diluted solution of the silane coupling agent, and the adhesion enhancing film 370 may be formed by spray-coating the lower and side surfaces of the interconnect layer 310 with a diluted solution of the silane coupling agent. The concentration of the diluted solution of the silane coupling agent is 0.1% to 10%, preferably 0.5% to 5%. At this stage, the thickest part of the adhesion enhancing films 270 and 370 may be about 20 nm to 30 nm, for example. Thereafter, washing with water, partial removal of the adhesion enhancing films 270 and 370 using a removal treatment solution such as an acidic solution, and drying are performed in this order. As a result, the adhesion enhancing films 270 and 370 having a thickness of about 3 nm to 8 nm are obtained.

After the formation of the adhesion enhancing films 270 and 370, as illustrated in FIG. 4C, an uncured resin film is attached to the A-side surface of the core layer 100 so as to cover the interconnect layer 210 and the adhesion enhancing film 270, and an uncured resin film is attached to the B-side surface of the core layer 100 so as to cover the interconnect layer 310 and the adhesion enhancing film 370. These resin films are cured by heat to form the insulating layers 220 and 320. The insulating layers 220 and 320 are formed of an insulating resin such as epoxy resin or polyimide resin. The insulating 220 layers and 320 may alternatively be formed by applying a liquid resin. The insulating layers 220 and 320 are each an example of a first insulating layer.

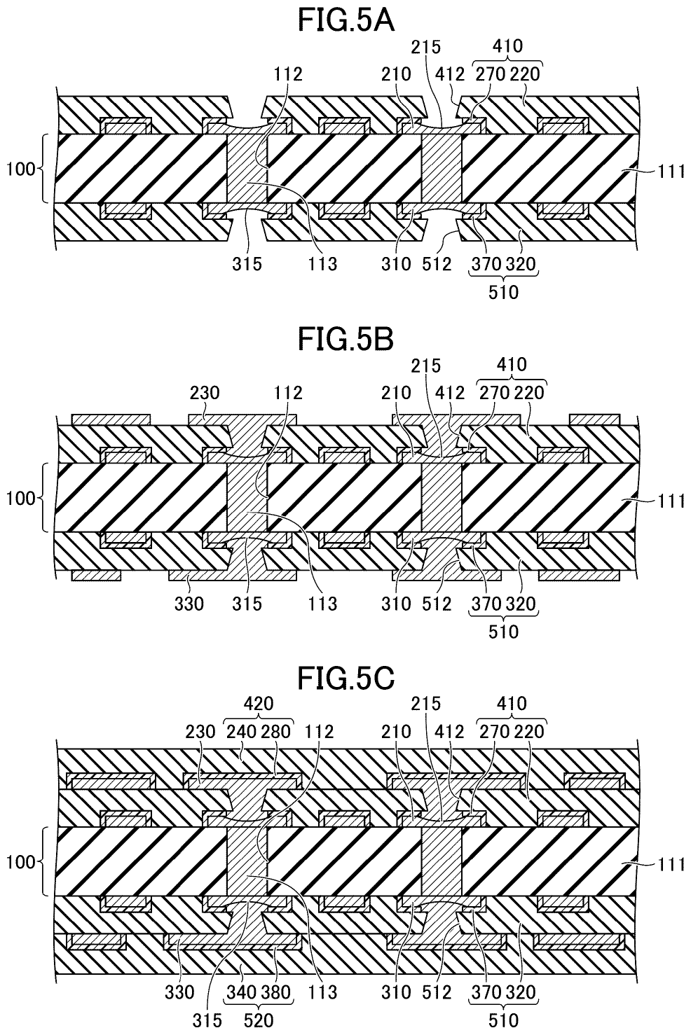

As illustrated in FIG. 5A, the via hole 412 reaching the interconnect layer 210 is formed in the insulating layer 410 (i.e., the insulating layer 220 and the adhesion enhancing film 270), and the via hole 512 reaching the interconnect layer 310 is formed in the insulating layer 510 (i.e., the insulating layer 320 and the adhesion enhancing film 370). In addition, the recess 215 is formed in the A-side surface of the interconnect layer 210, and the recess 315 is formed on the B-side surface of the interconnect layer 310.

Subsequently, as illustrated in FIG. 5B, the interconnect layer 230 including a via conductor positioned within the via hole 412 and the recess 215 and an interconnect pattern on the A-side surface of the insulating layer 220 is formed. The interconnect layer 330 including a via conductor positioned within the via hole 512 and the recess 315 and an interconnect pattern on the B-side surface of the insulating layer 320 is also formed.

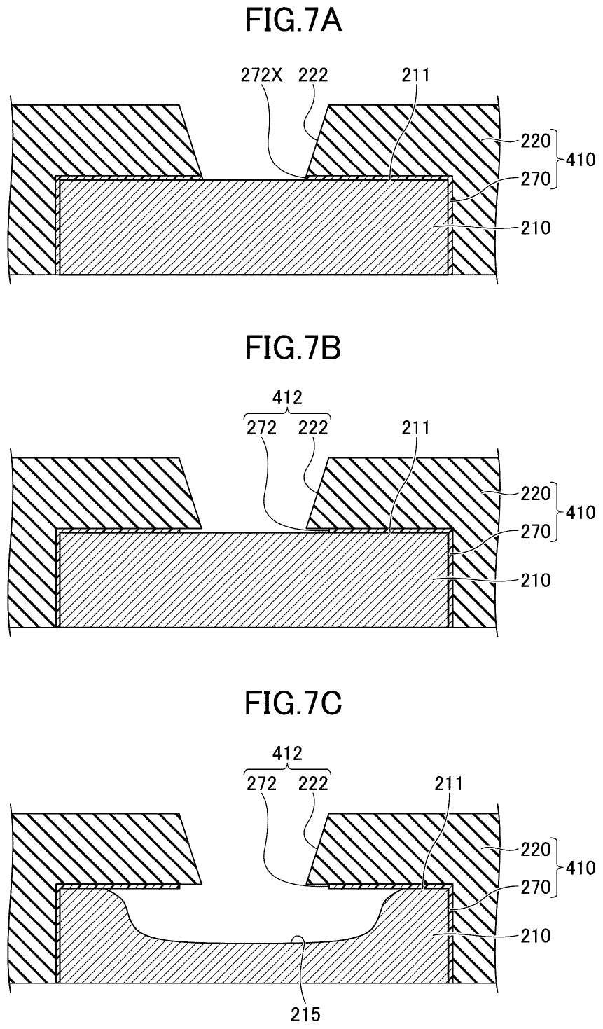

A method of forming the via hole 412, the recess 215, and the interconnect layer 230 will now be described. FIGS. 7A through 7C to FIGS. 9A and 9B are cross-sectional views illustrating an example of a method of forming via holes, recesses and interconnect layers.

First, as illustrated in FIG. 7A, the insulating layer 410 (i.e., the insulating layer 220 and the adhesion enhancing film 270) is machined with a laser to form the hole portion 222 in the insulating layer 220 and a hole portion 272X in the adhesion enhancing film 270. The hole portion 222 penetrates the insulating layer 220, and the hole portion 272X penetrates the adhesion enhancing film 270. The hole portions 222 and 272X are formed so as to overlap the interconnect layer 210 in plan view. The insulating layer 220 and the adhesion enhancing film 270 may alternatively be machined by a drill. The hole portion 222 is an example of a first hole portion.

Next, desmearing is performed. As a result of the desmearing, as illustrated in FIG. 7B, the portion of the adhesion enhancing film 270 exposed to the hole portion 272X is wet etched through the hole portion 222, which results in the formation of the hole portion 272 in the adhesion enhancing film 270 which is wider than the lower end of the hole portion 222. The hole portion with the 272 overlaps interconnect layer 210 in plan view. These steps achieve the formation of the via hole 412 including the hole portions 222 and 272 in the insulating layer 410. The interconnect layer 210 is exposed through the via hole 412. For desmearing, for example, sodium permanganate solution is used. The hole portion 272 is an example of a second opening.

It may be noted that it is not necessary to form the hole portion 272X in the adhesion enhancing film 270 when machining with a laser or a drill. Even without the presence of the hole portion 272X, the desmearing through the hole portion 222 is able to form the hole portion 272.

As illustrated in FIG. 7C, the interconnect layer 210 is wet etched through the hole portions 222 and 272 to form the recess 215 in the upper surface 211 of the interconnect layer 210. For example, sodium persulfate is used for the wet etching of the interconnect layer 210.

During the formation of the recess 215, the presence of the hole portion 272 in the adhesion enhancing film 270 causes the interconnect layer 210 to be wet etched in a larger area from the beginning than when the hole portion 272 is not provided. As a result, wet etching progresses more strongly in the thickness direction. Further, in the portion where the adhesion enhancing film 270 remains, the etchant is less likely to penetrate into the interface between the interconnect layer 210 and the adhesion enhancing film 270 than the interface between the interconnect layer 210 and the insulating layer 220 which would exist if the adhesion enhancing film 270 were not provided. That is, wet etching in the direction parallel to the upper surface of the interconnect layer 210 is less likely to occur. Therefore, the recess 215 having the illustrated cross-sectional shape is formed.

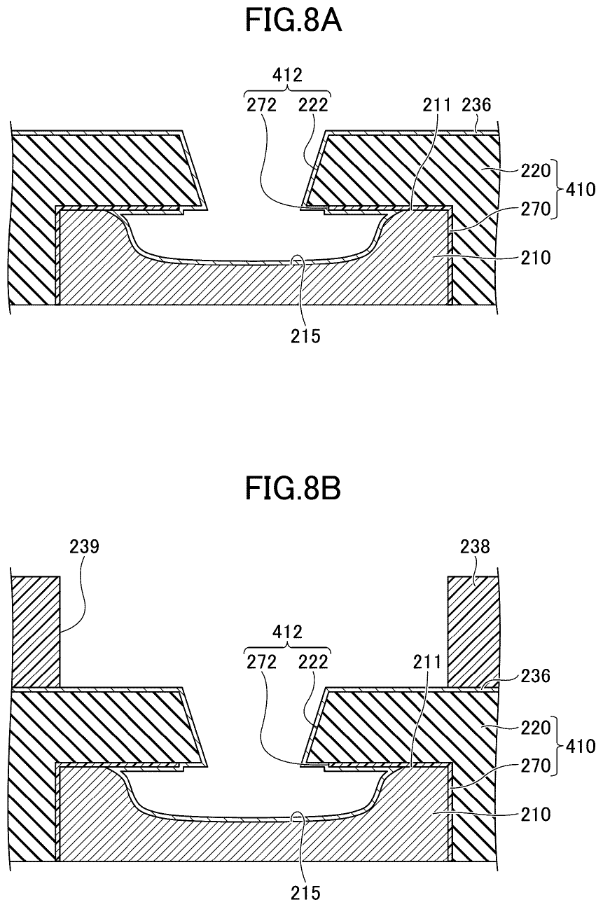

Subsequently, as illustrated in FIG. 8A, the seed layer 236 made of copper or the like is formed so as to directly cover the surface of the recess 215, the portion of the lower surface 411 of the insulating layer 410 exposed to the recess 215, the inner wall surface of the via hole 412, and the A-side surface of the insulating layer 410. The seed layer 236 may be formed by, for example, sputtering or electroless plating.

As illustrated in FIG. 8B, a plating resist layer 238 is formed on the seed layer 236. The plating resist layer 238 is exposed and developed to form an opening 239 in the plating resist layer 238.

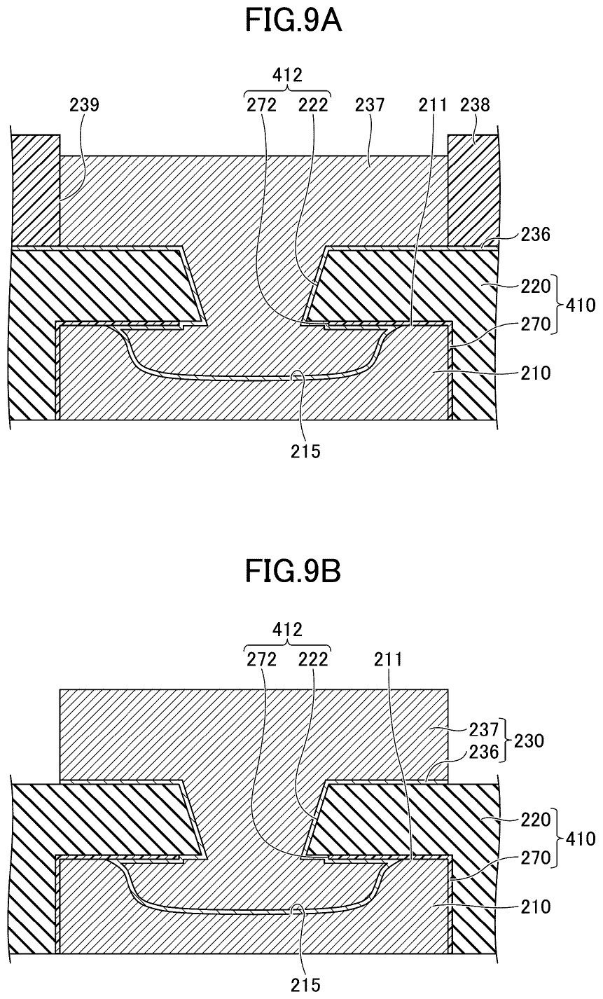

As illustrated in FIG. 9A, the plating layer 237 made of copper or the like is formed in the opening 239 of the plating resist layer 238 by an electrolytic plating method, using the seed layer 236 as a power supply path for plating.

Subsequently, as illustrated in FIG. 9B, the plating resist layer 238 is removed. Further, with the plating layer 237 being used as a mask, the seed layer 236 is removed by flash etching. Through these steps, the interconnect layer 230 including the seed layer 236 and the plating layer 237 is effectively formed.

The via hole 512 and the interconnect layer 330 may also be formed in substantially the same manner as the via hole 412 and the interconnect layer 230.

After the interconnect layers 230 and 330 are formed, as illustrated in FIG. 5C, the adhesion enhancing film 280 is formed on the upper and side surfaces of the interconnect layer 230, and the adhesion enhancing film 380 is formed on the lower and side surfaces of the interconnect layer 330. The adhesion enhancing films 280 and 380 may be formed in substantially the same manner as the adhesion enhancing films 270 and 370. Further, the insulating layer 240 is formed on the insulating layer 220 so as to cover the interconnect layer 230 and the adhesion enhancing film 280. The insulating layer 340 is also formed under the insulating layer 320 so as to cover the interconnect layer 330 and the adhesion enhancing film 380. The insulating layers 240 and 340 may be formed in substantially the same manner as the insulating layers 220 and 320. The insulating layers 240 and 340 are each an example of a first insulating layer.

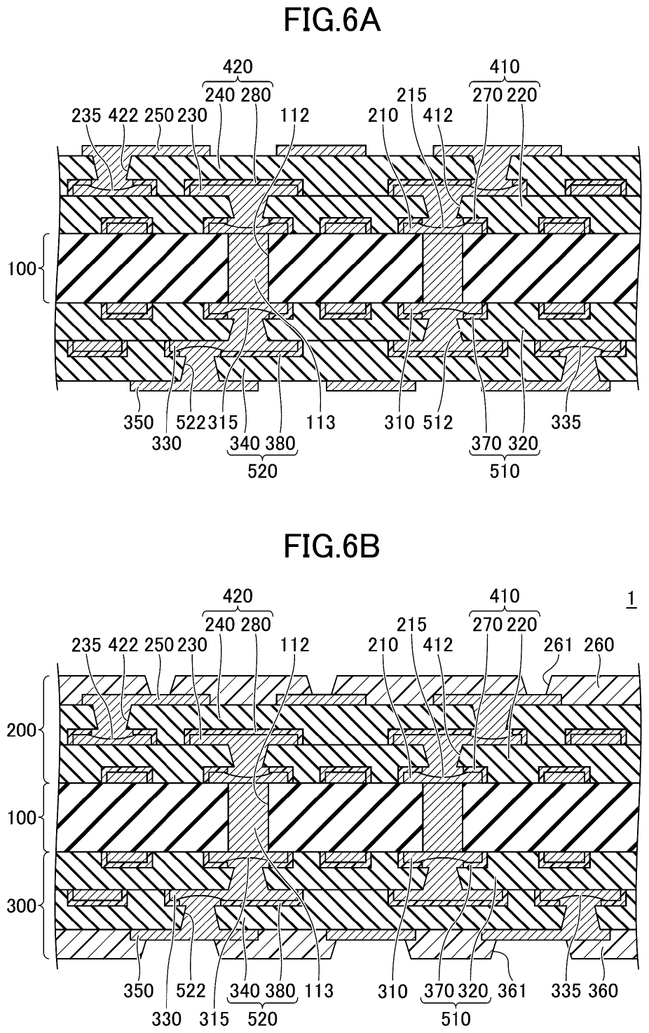

As illustrated in FIG. 6A, the via hole 422 reaching the interconnect layer 230 is formed in the insulating layer 420 (i.e., the insulating layer 240 and the adhesion enhancing film 280), and the via hole 522 reaching the interconnect layer 330 is formed in the insulating layer 520 (i.e., the insulating layer 340 and the adhesion enhancing film 380). Further, the recess 235 is formed on the A-side surface of the interconnect layer 230, and the recess 335 is formed on the B-side surface of the interconnect layer 330. Subsequently, the interconnect layer 250 including a via conductor positioned within the via hole 422 and the recess 235 and an interconnect pattern on the A-side surface of the insulating layer 240 is formed. Also, the interconnect layer 350 including a via conductor located within the via hole 522 and the recess 335 and an interconnect pattern on the B-side surface of the insulating layer 340 is formed.

The via hole 422, the recess 235, and the interconnect layer 250 may be formed in substantially the same manner as the via hole 412, the recess 215, and the interconnect layer 230. The via hole 522, the recess 335, and the interconnect layer 350 may be formed in substantially the same manner as the via hole 412, the recess 215, and the interconnect layer 230.

As illustrated in FIG. 6 6B, the solder resist layer 260 is formed on the insulating layer 240 and the solder resist layer 360 is formed under the insulating layer 340. Thereafter, the opening 261 is formed in the solder resist layer 260 and the opening 361 is formed in the solder resist layer 360.

By following these steps, the successful manufacture of the interconnect substrate 1 according to the embodiment is achieved.

In the interconnect substrate 1, when the portion between the first point 11 and the second point 12 on the surface of the recess 215 is approximated by a curve with only one inflection point 19, the first angle θ1 is less than 90 degrees, the second angle θ2 is greater than 90 degrees, and the third angle θ3 is greater than 90 degrees. As a result, during the formation of the plating layer 237, the plating liquid easily wets and spreads to the edge of the recess 215, so that the recess 215 is easily filled with the interconnect layer 230 having the seed layer 236 and the plating layer 237. That is, a gap is unlikely to remain in the recess 215. The reliability of connection between the interconnect layer 210 and the interconnect layer 230 is thus effectively improved.

In particular, when the angle θ1 is from 10 degrees to 40 degrees, the angle θ2 is from 120 degrees to 160 degrees, and the angle θ3 is from 120 degrees to 160 degrees, the plating liquid easily wets and spreads to the edge of the recess 215 during the formation of the plating layer 237.

In the interconnect substrate 1, it may sometimes be difficult to distinguish between the adhesion enhancing film 270 and the insulating layer 220. Even in such a case, the presence of the adhesion enhancing film 270 is effectively estimated by the presence of the second region 32 and the third region 33 having different filler densities.

The plane shape of the via hole does not have to be a circle. When the plane shape of the via hole is not a circle, the center of the circle obtained by approximating the plane shape of the via hole may be set as the center in plan view.

The surface of the recess 215 may be roughened between the formation of the recess 215 by wet etching and the formation of the seed layer 236.

According to the disclosed technique, the reliability of connections between interconnect layers is effectively improved.

The present disclosures non-exhaustively include the subject matter set out in the following clauses.

Clause 1. A method of making an interconnect substrate, comprising:
forming a first interconnect layer having a first surface;
forming an adhesion enhancing film covering the first interconnect layer;
forming a first insulating layer on the adhesion enhancing film;
forming a first hole portion that penetrates the first insulating layer, and overlaps the first interconnect layer in plan view;
wet etching the adhesion enhancing film through the first hole portion to form a second hole portion that penetrates the adhesion enhancing film and is wider than a lower end of the first hole portion;
wet etching the first interconnect layer through the first hole portion and the second hole portion to form a recess in the first surface; and
forming a second interconnect layer on the first insulating layer in contact with the first interconnect layer through the first hole portion and the second hole portion.

Clause The 2. method of making an interconnect substrate as recited in clause 1, wherein the adhesion enhancing film includes a silane coupling agent.

Clause 3. The method of making an interconnect substrate as recited in clause 1, wherein the wet etching the first interconnect layer includes using an acidic solution.

Clause 4. The method of making an interconnect substrate as recited in clause 1, wherein the wet etching the adhesion enhancing film includes using a sodium permanganate solution.

Clause 5. The method of making an interconnect substrate as recited in clause 1, wherein an insulating layer which is a laminate of the adhesion enhancing film and the first insulating layer has a second surface facing the first surface,
wherein, in a cross section including a center line that is perpendicular to the second surface and passes through a center of an upper edge of the first hole portion in plan view,
a surface of the recess includes a first point located at an edge of the recess and a second point located on the center line, and
when a portion of the surface of the recess between the first point and the second point is approximated by a curve with only one inflection point,
   a first angle between a first line segment connecting the first point and a third point and a line segment extending from the first point to the center line on the second surface is less than 90 degrees,
   a second angle between the first line segment and a second line segment connecting the third point and a fourth point is greater than 90 degrees,
   a third angle between the second line segment and a third line segment connecting the fourth point and the second point is greater than 90 degrees,
   the third point is a point where a curvature of the curve is maximum between the first point and the inflection point, and
   the fourth point is a point where the curvature of the curve is maximum between the second point and the inflection point.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An interconnect substrate comprising:
a first interconnect layer having a first surface in which a recess is formed;
an insulating layer that has a second surface facing the first surface and covers the first interconnect layer;
a via hole overlapping the first interconnect layer in plan view and penetrating the insulating layer; and
a second interconnect layer formed on the insulating layer and situated in contact with the first interconnect layer through the via hole,
wherein in a cross section including a center line that is perpendicular to the second surface and passes through a center of an upper edge of the via hole in plan view,
a surface of the recess includes a first point located at an edge of the recess and a second point located on the center line, and
when a portion of the surface of the recess between the first point and the second point is approximated by a curve with only one inflection point,
a first angle between a first line segment connecting the first point and a third point and a line segment extending from the first point to the center line on the second surface is less than 90 degrees,
a second angle between the first line segment and a second line segment connecting the third point and a fourth point is greater than 90 degrees,
a third angle between the second line segment and a third line segment connecting the fourth point and the second point is greater than 90 degrees,
the third point is a point where a curvature of the curve is maximum between the first point and the inflection point, and
the fourth point is a point where the curvature of the curve is maximum between the second point and the inflection point.

2. The interconnect substrate as claimed in claim 1, wherein the first angle is from 10 degrees to 40 degrees,
the second angle is from 120 degrees to 160 degrees, and
the third angle is from 120 degrees to 160 degrees.

3. The interconnect substrate as claimed in claim 1, wherein, in the cross section, a first region of the insulating layer extending to a depth of 2 μm or less from a portion, facing the recess, of the second surface includes a second region including an inner wall surface of the via hole and a third region connected to the second region and positioned between the second region and the first point in plan view, and
wherein a density of a filler in the second region is higher than a density of the filler in the third region.

4. The interconnect substrate as claimed in claim 1, wherein the second interconnect layer includes a first metal layer and a second metal layer, the first metal layer covering the surface of the recess, a portion of the second surface of the insulating layer, and an inner wall surface of the via hole, the second metal layer being provided on the first metal layer to fill the recess and the via hole.

5. The interconnect substrate as claimed in claim 1, wherein the via hole has an inverted truncated conical shape with a diameter thereof decreasing from an upper surface of the insulating layer toward the second surface.

6. The interconnect substrate as claimed in claim 3, wherein the third region of the insulating layer includes, at the second surface, an adhesion enhancing film in contact with the first surface of the first interconnect layer.

7. The interconnect substrate as claimed in claim 6, wherein the second surface of the insulating layer in the second region is free of any adhesion enhancing film.
